(19) United States
(12) Patent Application Publication
(10) Pub. No.: US 2006/0292720 A1
(43) Pub. Date: Dec. 28, 2006

(54) Semiconductor laser device

(75) Inventor: Tohru Nishikawa, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/406,408

(22) Filed: Apr. 19, 2006

(30) Foreign Application Priority Data
Jun. 23, 2005 (JP) 2005-182730

(51) Int. Cl. H01L 21/00; H01L 33/00

(52) U.S. Cl. 438/26; 257/99

(57) ABSTRACT

When a laser irradiation direction is assumed as a forward direction, a front end surface of a die pad (104), a front end surface of a resin mold member (106), and a front end surface of a semiconductor laser element (101) are sequentially disposed in this order from the front side, and a distance from the front end surface of the semiconductor laser element (101) to the front end surface of the die pad (104) is set to such a predetermined length that an amount of laser beams blocked by the die pad (104) does not exceed a predetermined amount. Thereby, the die pad (104) can be extended forwardly from the semiconductor laser element (101), and thus it is possible to secure excellent heat radiation ability suitable for mounting a thin and high-power semiconductor laser element.

### BACKGROUND OF THE INVENTION

1. Field of the Invention

The present invention relates to a semiconductor laser device having a semiconductor laser element mounted thereon.

2. Description of the Related Art

Semiconductor laser devices are practically used as light sources for recording and reproducing data on optical disks.

In recent years, with increase in requirement for high-speed recording on optical disks, high-power optical disks are required. On the other hand, with rapid spread of notebook computers and other mobile apparatuses, optical disk drives with decreased thickness have been required and semiconductor laser devices with decreased thickness have been also required similarly.

In order to accomplish decrease in thickness in conventional semiconductor laser devices, a package having a frame structure shown in FIGS. 15 and 16 has been developed. Hereinafter, the package structure for mounting a conventional semiconductor device is described with reference to FIGS. 15 and 16.

FIG. 15 is a perspective view of a package for mounting a conventional semiconductor device and FIG. 16 is a plan view of the package for mounting a conventional semiconductor device.

As shown in FIGS. 15 and 16, the conventional semiconductor laser device has a structure that a lead 2011 having a mount portion 2011M on which a semiconductor laser element 2001 is mounted and leads 2012 for drawing out other terminals are integrally sealed with a common resin mold member 2013. The resin mold member 2013 has a concave portion 2014 formed to expose to the outside the mount portion 2011M of the lead 2011 on which the semiconductor laser element 2001 is mounted and a part of the other leads 2012, and receive the semiconductor laser element 2001. In the concave portion 2014, the semiconductor laser element 2001 is electrically connected to the leads 2011 and 2012 through lead wires 2018 (for example, see Japanese Patent No. 3186684).

### SUMMARY OF THE INVENTION

However, such a structure is not suitable for mounting a high-power semiconductor laser element, since the portion for mounting the semiconductor laser element is narrow and a contact area with an external heat sink for externally radiating heat from the semiconductor laser element is not enough. Specifically, since the volume of a metal frame having excellent heat radiation ability is small in the vicinity of a front end surface of the semiconductor laser element, there is a problem that the heat from the front end surface of the semiconductor laser element having the greatest amount of radiation cannot be sufficiently radiated to the outside.

Therefore, an object of the present invention is to provide a semiconductor laser device having a decreased thickness and excellent heat radiation ability suitable for mounting a high-power semiconductor laser element.

According to an aspect of the present invention, there is provided a semiconductor laser device comprising: a semiconductor laser element which is a laser emitting element; a die pad for mounting thereon the semiconductor laser element with a sub mount interposed therebetween; a lead connected to an electrode of the semiconductor laser element through a wire; and a resin mold member covering the semiconductor laser element, the die pad and the lead, so that the semiconductor laser is exposed at least at an emission portion thereof and an end portion thereof opposed to a wire connection portion of the lead, wherein when an irradiation direction of the semiconductor laser element is assumed as a forward direction, a front end surface of the die pad, a front end surface of the resin mold member on the surface of the die pad on which the semiconductor laser element is mounted, and a front end surface of the semiconductor laser element are sequentially disposed in this order from the front side, and a distance from an emission point of the semiconductor laser element to the front end surface of the die pad is a predetermined length.

The predetermined length may be calculated from a vertical spreading angle of a laser beam irradiated from the semiconductor laser element and a height from the surface of the die pad to the emission point so that an amount of the laser beam blocked by the die pad does not exceed a predetermined amount.

In addition, the predetermined length may be greater than or equal to 300 μm.

The semiconductor laser device may further comprise a wing portion formed by allowing the die pad to extend through the resin mold member in a direction perpendicular to the irradiation direction of the semiconductor laser element.

The die pad may be allowed to further extend forwardly and a chamfer may be formed in the extended portion so that the amount of laser beams blocked by the die pad does not exceed a predetermined amount.

The resin mold member under the die pad may be opened so that the front end surface of the resin mold under the die pad member is positioned more backward than a rear end surface of the sub mount.

### BRIEF DESCRIPTION OF THE DRAWINGS

FIG. 1 is a longitudinal sectional view of a semiconductor laser device according to the present invention;

FIG. 2 is a plan view of the semiconductor laser device according to the invention;

FIG. 3A is a transverse sectional view of the semiconductor laser device according to the invention;

FIG. 3B is a transverse sectional view of the semiconductor laser device according to the invention;

FIG. 4 is a sectional view illustrating heat radiation paths in the semiconductor laser device provided with a heat sink;

FIG. 5 is a sectional view illustrating heat radiation paths in the semiconductor laser device according to the invention;

FIG. 6 is a diagram illustrating a heat distribution in a semiconductor laser element;

FIG. 7 is a diagram illustrating a positional relation between a die pad and emitted laser beams;

FIG. 8 is a diagram illustrating parameters for calculating a laser blocking amount of the semiconductor laser element;

FIG. 9 is a diagram illustrating calculation results of the parameters for calculating a laser blocking amount of the semiconductor laser element;

FIG. 10 is a sectional view illustrating the semiconductor laser device having been subjected to a chamfering process;

FIG. 11 is a diagram illustrating a chamfer forming method using a hammering process;

FIG. 12 is a diagram illustrating a chamfer forming method using a punch press;

FIG. 13 is a plan view illustrating a structure of a semiconductor laser device provided with a cap according to the invention;

FIG. 14 is a sectional view illustrating the semiconductor laser device provided with the cap according to the invention;

FIG. 15 is a perspective view of a package for mounting thereon a conventional semiconductor device; and

FIG. 16 is a plan view illustrating the package for mounting thereon a conventional semiconductor device.

### DESCRIPTION OF THE EMBODIMENTS

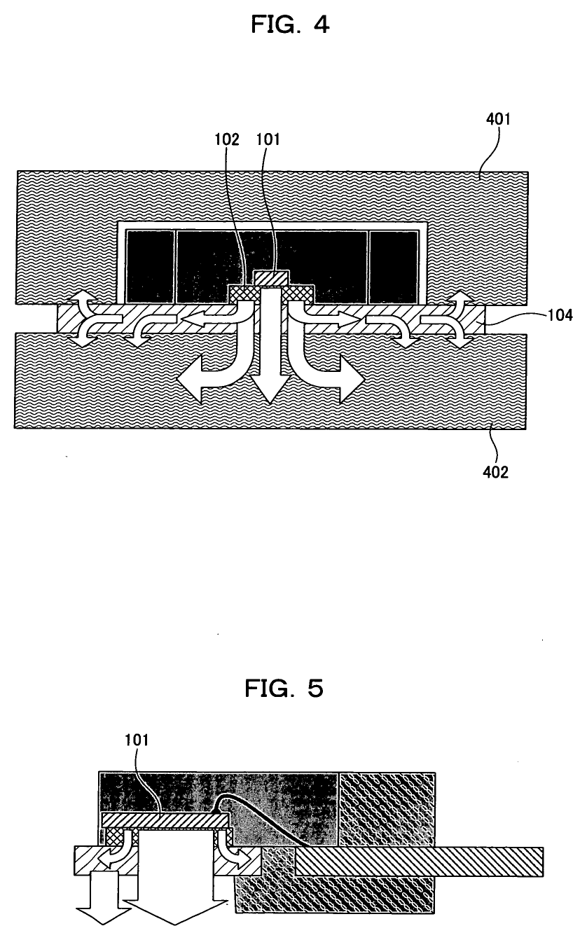

First, a semiconductor laser device according to the present invention will be described in brief with reference to FIGS. 4, 5, 6, and 7.

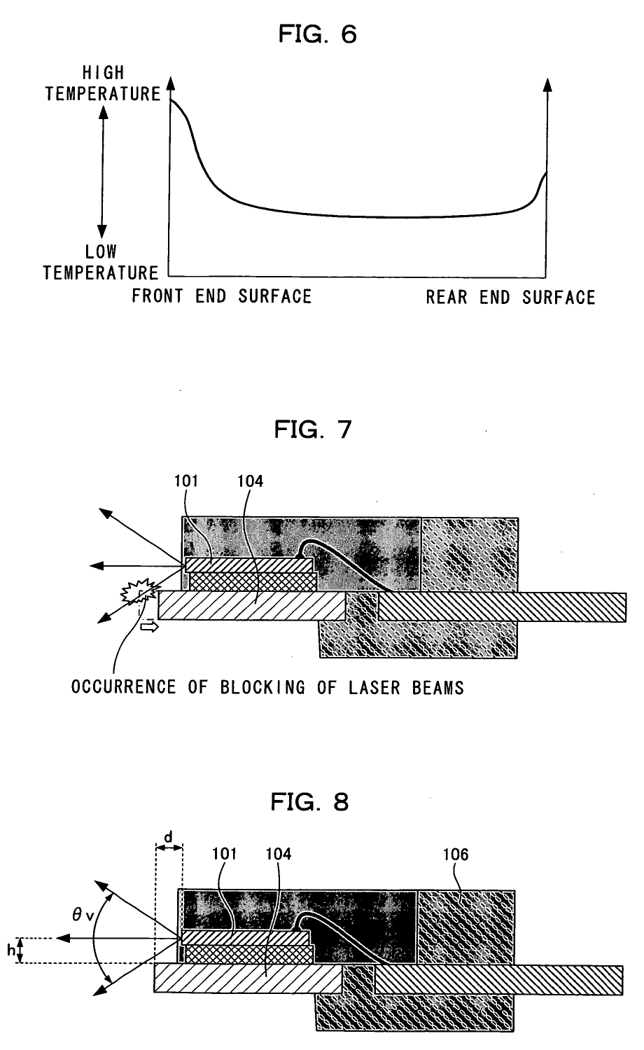

FIG. 4 is a sectional view illustrating heat radiation paths in the semiconductor laser device which is provided with a heat sink, FIG. 5 is a sectional view illustrating heat radiation paths in the semiconductor laser device according to the invention, FIG. 6 is a diagram illustrating a heat distribution in a semiconductor laser element, and FIG. 7 is a diagram illustrating a positional relation between a die pad and emitted laser beams.

In order to improve a heat radiation ability, the invention employs a structure that the volume of a semiconductor-laser mounting die pad 104 for mounting a semiconductor laser element 101 can be increased as long as a characteristic of the semiconductor laser element 101 is not damaged.

In a thin semiconductor laser device having a frame structure including the conventional example, as shown in FIG. 4, since heat radiation paths can be efficiently provided right below the semiconductor laser element as indicated by the arrows by disposing an upper heat sink 401 and a lower heat sink 402 on a die pad 104 on which the semiconductor laser element 101 with a sub mount 102 therebetween, the heat radiation ability is more excellent than that of a semiconductor laser device having a can structure.

However, in the high-power semiconductor laser element, it can be seen known from a temperature distribution of the semiconductor laser element 101 shown in FIG. 6 that an end portion, specifically, a front end surface, has a higher temperature than that of the central portion thereof and that the front end surface generally has a higher temperature distribution at the time of working. Accordingly, in order to accomplish more efficient radiation of heat, as shown in FIG. 5, it is important to extend the semiconductor-laser mounting die pad 104 forwardly from the front end surface of the semiconductor laser element 101 as great as possible. As a result, since the heat is also radiated from the front portion of the die pad 104 as indicated by the heat radiation paths of the arrows in the figure, a radiation effect is enhanced.

On the other hand, as shown in FIG. 7, when the semiconductor-laser mounting die pad 104 extends forwardly, laser beam emitted from the semiconductor laser element 101 are also irradiated downwardly as indicated by the arrow. Accordingly, when the die pad 104 extends to the range in which the laser beams are irradiated, the laser beams are blocked by the die pad 104. Therefore, it is necessary to establish a condition not causing the blocking of laser beams in a positional relation between the front end surface of the semiconductor-laser mounting die pad 104 and the front end surface of the semiconductor laser element 101.

Conventionally, in the front portion of the semiconductor laser device, the front end surface of the die pad is positioned at the more inside than that of the resin mold member and the front end surface of the semiconductor laser element is positioned at the more inside than the front end surface of the die pad. In addition, in the vicinity of the front end surface of the semiconductor laser element, the mount portion is recessed about an optical axis of the laser beams irradiated from the semiconductor laser element so as not to block the laser beams emitted from the semiconductor laser element. However, this structure is disadvantageous in the heat radiation ability.

Therefore, by setting a vertical spreading angle of the laser beams emitted from the semiconductor laser element 101, a height from the surface of the semiconductor-laser mounting die pad 104 to an emission point, and a distance between the front end surface of the semiconductor laser element 101 and the front end surface of the semiconductor-laser mounting die pad 104 and calculating the positional relation that the laser blocking amount of laser beams emitted from the semiconductor laser element is 1% by the use of the values as parameters, the maximum length in consideration of the laser blocking amount is secured without forming the die pad 104 in a concave form, thereby enhancing radiation efficiency.

On the basis of the calculation result, it is possible to provide a semiconductor laser device having the maximum heat radiation ability by determining the maximum length not affecting the characteristic thereof.

The vertical spreading angle of high-power laser beams is preferably 25° in maximum (FWHM) in consideration of market needs, but the maximum vertical spreading angle is set preferably to 30° so as to completely prevent the blocking of laser beams. The height from the surface of the die pad to the emission point is preferably 200 μm in minimum in consideration of a general specification.

In the semiconductor laser device having a high-power semiconductor laser element, it is the optimal condition that the distance between the front end surface of the semiconductor-laser mounting die pad and the front end surface of the semiconductor laser element 101 is set 300 μm or more on the basis of the two above-mentioned parameters and accuracy in disposition.

Actually, by further increasing the distance in accordance with the vertical spreading angle of laser beams or the height of the emission point, it is possible to obtain excellent heat radiation ability.

In addition, there is a method of forming a chamfer at the upper side of the front end surface of the semiconductor-laser mounting die pad 104 so as to further enhance the heat radiation ability. The distance in which the blocking of laser beams occurs can be made to extend as much as the chamfer by the use of the method, thereby further enhancing the heat radiation ability.

The method of forming a chamfer may be performed at the same time as performing a burr hammering process executed to remove burrs after a punch press, or may be performed by making an adjustment at the same time as performing the punch press to form a large R at the upper side of the front end surface of the semiconductor-laser mounting die pad 104. In this way, the chamfer can be easily formed without increase in cost.

In addition, the amount of heat radiation from the vicinity of the rear end surface of the semiconductor laser element is great. Accordingly, in order to accomplish efficient heat radiation, it is similarly necessary to enhance the heat radiation ability at the rear end surface of the semiconductor laser element, as well as the front end surface of the semiconductor laser element.

Therefore, in the invention, the mold right under the semiconductor laser element is removed to expose the die pad 104. This removal is advantageous for efficiently performing the heat radiation from the bottom portion of the semiconductor laser element. Thanks to this positional relation, the heat emitted from the semiconductor laser element can be radiated directly to the external heat sink without passing through other paths.

In the semiconductor laser device according to the invention, since the top surface and the front surface of a package are opened, a possibility that the semiconductor laser element should be damaged exists due to contact to the wires after completion of an assembly process and contact of particles to the semiconductor laser element. Accordingly, a solution to the possibility is required.

First, the contact from the upside can be avoided by adding a cap. In addition, by providing a cap positioning portion to the top surface of the resin mold member so as to easily position the cap, it is possible to easily perform the cap adding process.

Since the laser beams should not be blocked at the front surface, it is necessary to protect the semiconductor laser element while maintaining the optically opened state. In the invention, in order to avoid the contact of particles to the front end surface of the semiconductor laser element as much as possible, the semiconductor laser element is disposed in such a positional relation that the front end surface of the semiconductor laser element should not be protruded from the front end surface of the resin mold member.

Now, specific embodiments of the invention will be described in detail with reference to the figures.

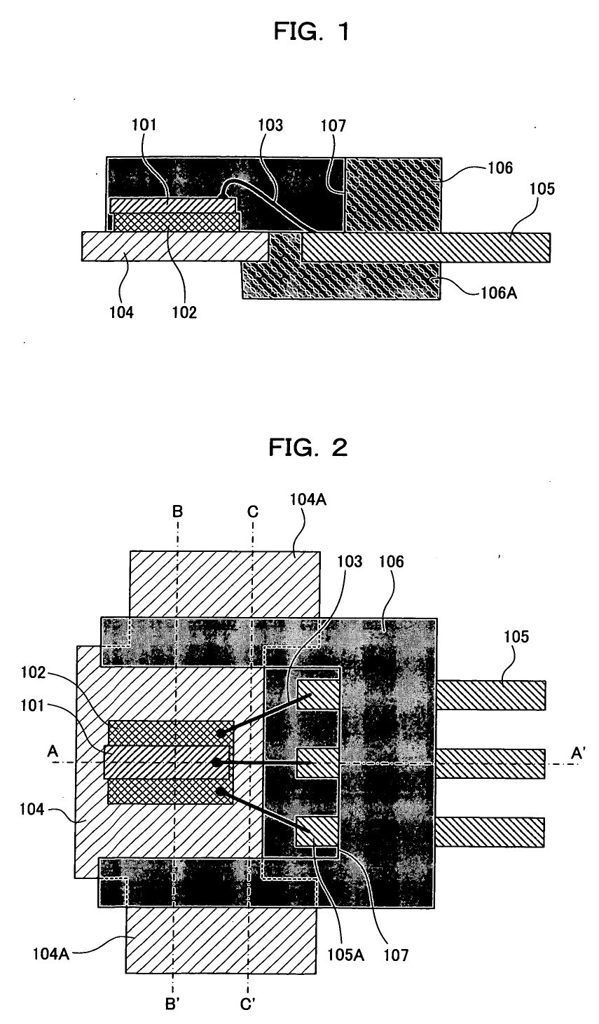

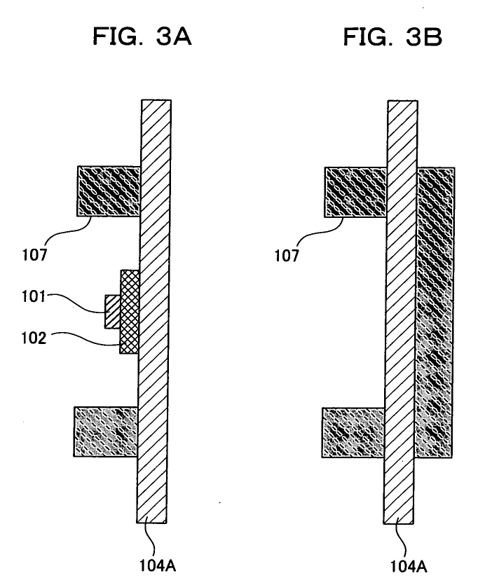

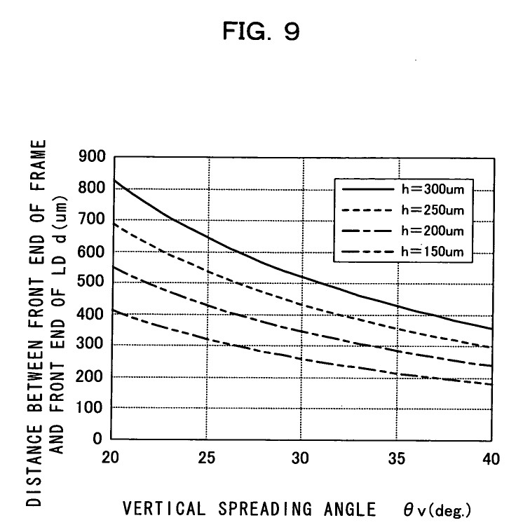

FIG. 1 is a longitudinal sectional view of the semiconductor laser device according to the invention and is a cross-sectional view taken along Line A-A′ of FIG. 2. FIG. 2 is a plan view of the semiconductor laser device according to the invention and FIG. 3 is a transverse sectional view of the semiconductor laser device according to the invention, where FIG. 3A is a cross-sectional view taken along Line B-B′ of FIG. 2 and FIG. 3B is a cross-sectional view taken along Line C-C′ thereof. FIG. 8 is a diagram illustrating parameters for calculating a laser blocking amount of the semiconductor laser element and FIG. 9 is a diagram illustrating the calculation result of the parameters for calculating the laser blocking amount of the semiconductor laser element.

As shown in FIGS. 1, 2, 3A, and 3B, the invention provides a semiconductor laser device having a basic structure that a semiconductor-laser-electrode drawing sub mount 102 on which the semiconductor laser element 101 is disposed is mounted on the semiconductor-laser mounting die pad 104 and an electrode drawn from the semiconductor laser element 101 is connected to a laser-electrode drawing inner portion 105A of the laser-electrode drawing lead 105 through an electrode drawing wire 103. The package has a basic structure that the semiconductor-laser mounting die pad 104 on which the semiconductor laser element 101 is mounted and the laser-electrode drawing lead 105 are integrally formed with the resin mold member 106. The resin mold member 106 has a basic structure including a portion on which the semiconductor laser element 101 is mounted and a concave portion 107 for forwardly drawing the laser beams emitted from the semiconductor laser element 101. The resin mold member 106 has such a shape that at least an emission portion of the semiconductor laser element 101 and an external terminal portion of the laser-electrode drawing lead 105 are exposed depending upon necessary emission efficiency and preferably includes the semiconductor laser element, the die pad, and the lead.

In the present embodiment, since a high-power semiconductor laser element is basically provided, it is most important to secure the heat radiation ability.

From the view point of the heat radiation ability, as the thickness of the semiconductor-laser mounting die pad 104 becomes larger, it becomes more advantageous. However, from the view point of mass workability, it is preferable that the thickness of the die pad is set in the range of 0.35 mm to 0.45 mm.

A copper material having excellent heat radiation ability and an excellent workability can be preferably used as a material for a frame including the semiconductor-laser mounting die pad 104 and the laser-electrode drawing lead 105.

Specifically, in order to secure the heat radiation ability while preventing the blocking of laser beams in the high-power semiconductor laser element, as shown in FIG. 8, the vertical spreading angle θv of the laser beams irradiated from the semiconductor laser element 101, the height h from the surface of the semiconductor-laser mounting die pad 104 to the emission point, and the distance d from the front end surface of the semiconductor laser element 101 to the front end surface of the semiconductor-laser mounting die pad 104 are set. Then, by using them as parameters, as shown in the graph of FIG. 9 illustrating the relations among the vertical spreading angle θv of the laser beams irradiated from the semiconductor laser element 101 in which the laser blocking amount is 1%, the height h from the surface of the semiconductor-laser mounting die pad 104 to the emission point, and the distance d from the front end surface of the semiconductor laser element 101 to the front end surface of the semiconductor-laser mounting die pad 104 are set, a positional relation is calculated that the blocking amount of laser beams emitted from the semiconductor laser element is 1%. When the irradiation direction of the semiconductor laser device is assumed as the forward direction, the front end surface of the die pad 104, the front end surface of the resin mold member 106, and the front end surface of the semiconductor laser element 101 are sequentially disposed in that order. Then, the distance from the front end surface of the semiconductor laser element 101 to the front end surface of the semiconductor-laser mounting die pad 104 is used as the calculated distance d.

In this way, by acquiring the maximum distance d not affecting the characteristic, it is possible to provide a semiconductor laser device having the maximum heat radiation ability.

The vertical spreading angle of the high-power laser beams is preferably 25° in maximum (FWHM) in consideration of market needs, but the maximum vertical spreading angle is set preferably to 30° so as to completely prevent the blocking of laser beams. The height from the surface of the die pad 104 to the emission point is preferably 200 μm in minimum in consideration of a general specification.

In the semiconductor laser device having a high-power semiconductor laser element, by setting the distance between the front end surface of the semiconductor-laser mounting die pad 104 and the front end surface of the semiconductor laser element 101 to about 300 μm on the basis of the two above-mentioned parameters and accuracy in disposition, the optimal heat radiation characteristic is obtained while preventing the blocking of laser beams.

Actually, by further increasing the distance d in accordance with the vertical spreading angle θv of laser beams or the height h of the emission point, it is possible to obtain excellent heat radiation ability. As one example thereof, when θv is 30° and h is 250 μm, the distance d can be increased to 400 μm in maximum because h is large.

In addition, by forming a wing portion for extending the semiconductor-laser mounting die pad, which is obtained by allowing the die pad 104 to extend through the resin mold member 106, in the lateral portion of the semiconductor laser device, it is possible to enhance the heat radiation efficiency.

In this way, when the irradiation direction of laser beams is assumed as the forward direction, the semiconductor laser device is constructed so that the front end surface of the die pad 104, the front end surface of the resin mold member 106, and the front end surface of the semiconductor laser element 101 are sequentially disposed in that order from the front side. In addition, the distance d from the front end surface of the semiconductor laser element 101 to the front end surface of the semiconductor laser-mounting die pad 104 is calculated on the basis of the vertical spreading angle θv of the semiconductor laser element 101 and the height h from the surface of the semiconductor-laser mounting die pad 104 to the emission point. Accordingly, since the die pad 104 can extend forwardly from the semiconductor laser element 101 as much as possible while preventing the blocking of laser beams, it is possible to secure excellent heat radiation ability.

A semiconductor laser device of which the heat radiation ability is enhanced more than the above-mentioned semiconductor laser device will be described with reference to FIGS. 1, 5, 6, 10, 11, and 12.

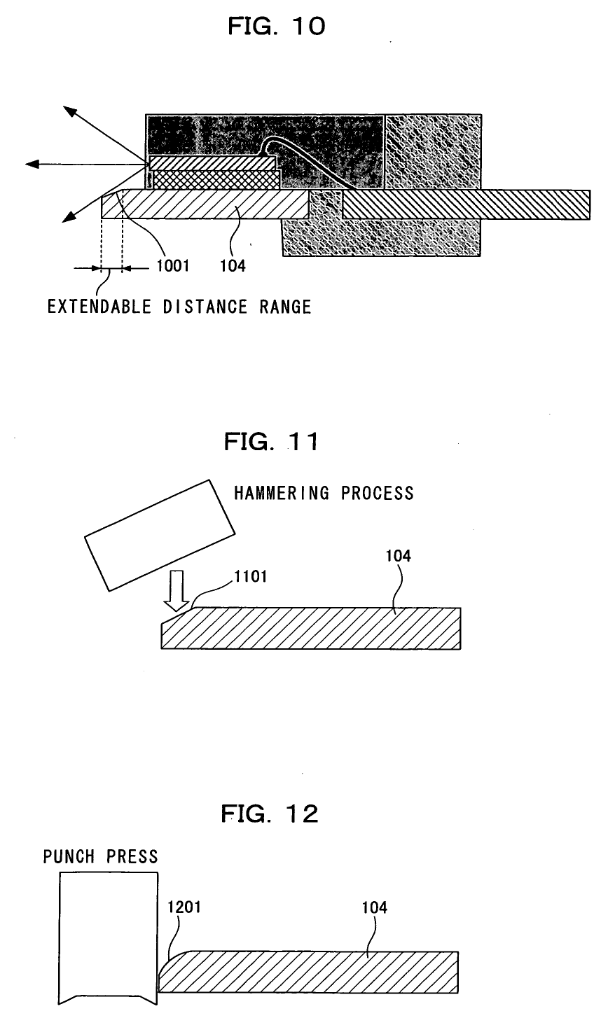

FIG. 10 is a cross-sectional view illustrating the semiconductor laser device having been subjected to a chamfering process, FIG. 11 is a diagram illustrating a chamfer forming method using a hammering process, and FIG. 12 is a diagram illustrating a chamfer forming method using a punch press.

First, as shown in FIG. 10, the front end of the semiconductor-laser mounting die pad 104 can be allowed to further and a chamfered portion 1001 can be formed at the upper surface of the extended portion. The chamfered portion is added to the die pad 104 and the chamfering angle of the chamfered portion is set such that the amount of laser beams blocked by the chamfered portion 1001 of the die pad 104 is less than or equal to a predetermined amount. By using such a method, the distance d in which the blocking of laser beams occurs can extend as much as the chamfered portion, thereby further enhancing the heat radiation ability.

In the method of forming the chamfered portion, a hammered chamfered portion 1101 may be formed by a predetermined hammering process at the same time as performing a burr hammering process executed to remove burrs after the punch press as shown in FIG. 11, or a rounded chamfered portion 1201 having a large R may be formed at the upper surface of the front end surface of the semiconductor-laser mounting die pad 104 by making an adjustment at the same time as performing the punch press as shown in FIG. 12. In this way, the chamfered portion can be easily formed without increase in cost.

The distance which can extend through the process depends upon the thickness of the semiconductor-laser mounting die pad 104. When the thickness is in the range of 0.35 mm to 0.45 mm, the distance can extend by 0.1 mm through the hammering process or the rounding process.

As shown in FIG. 6, the amount of heat radiated from the vicinity of the rear end surface of the semiconductor laser element is great. Accordingly, in order to accomplish efficient heat radiation, it is similarly necessary to enhance the heat radiation ability at the rear end surface of the semiconductor laser element 101, as well as at the front end surface of the semiconductor laser element 101.

Therefore, in the semiconductor laser device according to the invention, as shown in FIG. 1, the front end surface of the lower mode member 106A is positioned backwardly from the rear end surface of the sub mount 102. This is advantageous for efficiently performing the heat radiation from the bottom portion of the semiconductor laser element. Thanks to this positioning, as shown in FIG. 5, the heat emitted from the semiconductor laser element 101 can be radiated directly to the external heat sink without passing through other paths.

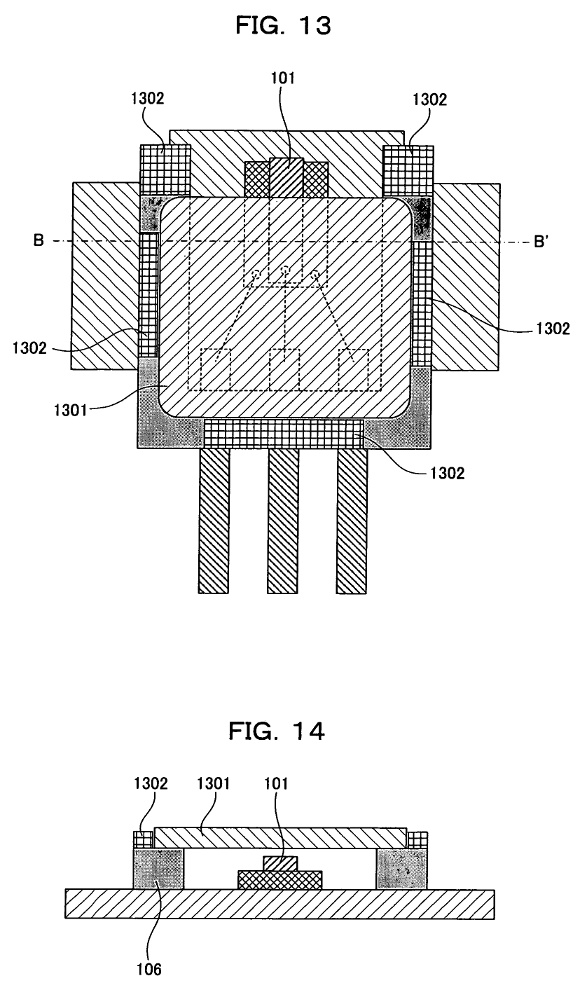

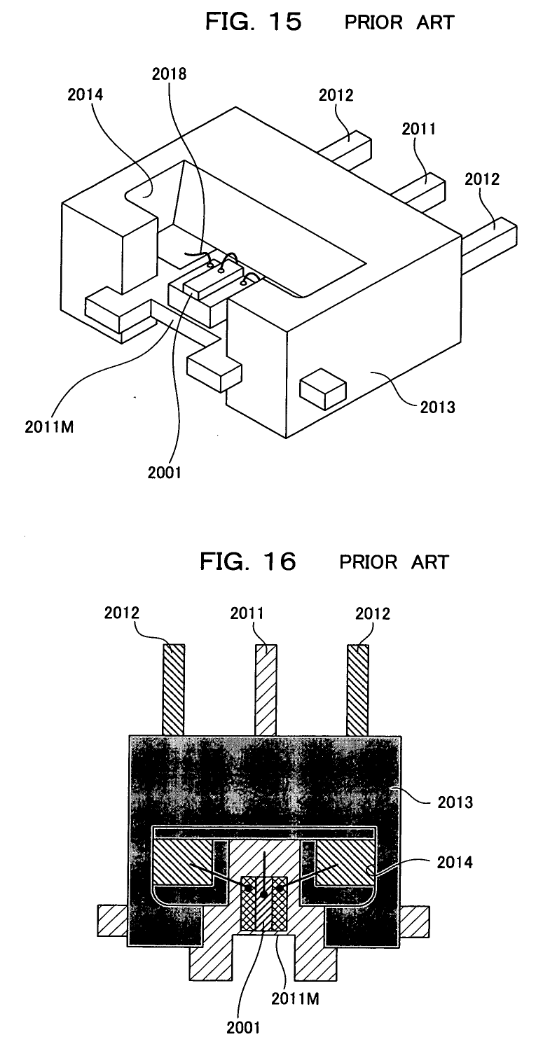

In the semiconductor laser device according to the invention, since the top surface and the front surface of a package are opened, a possibility that the semiconductor laser element should be damaged exists due to contact to the wires after completion of an assembly process and contact of particles to the semiconductor laser element. Accordingly, a solution to the possibility is required. Such a solution is described with reference to FIGS. 13 and 14.

FIG. 13 is a plan view illustrating a structure of the semiconductor laser device provided with a cap according to the invention and FIG. 14 is a sectional view illustrating the semiconductor laser device provided with the cap according to the invention, which is a cross-sectional view taken along Line B-B′ of FIG. 13.

First, the contact from the upside can be avoided by adding a cap 1301 so as to cover the opening of the resin mold member 106 in the semiconductor-laser device from the upside as shown in FIGS. 13 and 14. In addition, by providing cap positioning portions 1302 to the top surface of the resin mold member 106 so as to easily position the cap 1301, it is possible to easily perform the cap adding process.

Since the laser beams should not be blocked at the front surface, it is necessary to protect the semiconductor laser element 101 while maintaining the optically opened state. In the invention, in order to avoid the contact of particles to the front end surface of the semiconductor laser element 101 as much as possible, the semiconductor laser element 101 is disposed in such a positional relation that the front end surface of the semiconductor laser element 101 should not be protruded from the front end surface of the resin mold member 106.

On the other hand, although the semiconductor-laser mounting die pad 104 on which the semiconductor laser element 101 is mounted and the laser-electrode drawing leads 105 have been separated from each other in the structures according to the invention described above, one of the laser-electrode drawing leads 105 may be formed integrally with the semiconductor-laser mounting die pad 104 if only it does not hinder the driving of the semiconductor laser element 101.

What is claimed is:

1. A semiconductor laser device, comprising:
a semiconductor laser element that is a laser emitting element;
a die pad for mounting thereon the semiconductor laser element through a sub mount interposed therebetween;
a lead connected to an electrode of the semiconductor laser element through a wire; and
a resin mold member covering the semiconductor laser element, the die pad and the lead so that the semiconductor layer is exposed at least at an emission portion thereof and an end portion thereof opposed to a wire connection portion of the lead, wherein
when an irradiation direction of the semiconductor laser element is assumed as a forward direction, a front end surface of the die pad, a front end surface of the resin mold member on the surface of the die pad on which the semiconductor laser element is mounted, and a front end surface of the semiconductor laser element are sequentially disposed in this order from the front, and a distance from the emission point of the semiconductor laser element to the front end surface of the die pad is a predetermined length.

2. The semiconductor laser device according to claim 1, wherein the predetermined length is calculated from a vertical spreading angle of a laser beam irradiated from the semiconductor laser element and a height from the surface of the die pad to the emission point so that an amount of the laser beam blocked by the die pad is less than or equal to a predetermined amount.

3. The semiconductor laser device according to claim 1, wherein the predetermined length is not less than 300 μm.

4. The semiconductor laser device according to claim 1, wherein the die pad has a wing portion extending through the resin mold member in a direction perpendicular to the irradiation direction of the semiconductor laser element.

5. The semiconductor laser device according to claim 2, wherein the die pad has a wing portion extended through the resin mold member in a direction perpendicular to the irradiation direction of the semiconductor laser element.

6. The semiconductor laser device according to claim 1, wherein the die pad is further extended forwardly and a chamfer is formed in the extended portion so that an amount of laser beams blocked by the die pad does not exceed a predetermined amount.

7. The semiconductor laser device according to claim 2, wherein the die pad is further extended forwardly and a chamfer is formed in the extended portion so that an amount of laser beams blocked by the die pad does not exceed a predetermined amount.

8. The semiconductor laser device according to claim 4, wherein the die pad is further extended forwardly and a chamfer is formed in the extended portion so that an amount of laser beams blocked by the die pad does not exceed a predetermined amount.

9. The semiconductor laser device according to claim 5, wherein the die pad is further extended forwardly and a chamfer is formed in the extended portion so that an amount of laser beams blocked by the die pad does not exceed a predetermined amount.

10. The semiconductor laser device according to claim 1, wherein the resin mold member under the die pad is opened so that the front end surface of the resin mold member under the die pad is positioned more backward than a rear end surface of the sub mount.

11. The semiconductor laser device according to claim 2, wherein the resin mold member under the die pad is opened so that the front end surface of the resin mold member under the die pad is positioned more backward than a rear end surface of the sub mount.

12. The semiconductor laser device according to claim 4, wherein the resin mold member under the die pad is opened so that the front end surface of the resin mold member under the die pad is positioned more backward than a rear end surface of the sub mount.

13. The semiconductor laser device according to claim 5, wherein the resin mold member under the die pad is opened so that the front end surface of the resin mold member under the die pad is positioned more backward than a rear end surface of the sub mount.

14. The semiconductor laser device according to claim 6, wherein the resin mold member under the die pad is opened so that the front end surface of the resin mold member under the die pad is positioned more backward than a rear end surface of the sub mount.

15. The semiconductor laser device according to claim 7, wherein the resin mold member under the die pad is opened so that the front end surface of the resin mold member under the die pad is positioned more backward than a rear end surface of the sub mount.

16. The semiconductor laser device according to claim 8, wherein the resin mold member under the die pad is opened so that the front end surface of the resin mold member under the die pad is positioned more backward than a rear end surface of the sub mount.

17. The semiconductor laser device according to claim 9, wherein the resin mold member under the die pad is opened so that the front end surface of the resin mold member under the die pad is positioned more backward than a rear end surface of the sub mount.
